(19) United States
(12) Patent Application Publication
(10) Pub. No.: US 2024/0093020 A1
(43) Pub. Date: Mar. 21, 2024

(54) RESIN COMPOSITION, ADHESIVE SHEET, PREPREG, AND LAMINATE

(71) Applicant: Risho Kogyo Co., Ltd., Osaka (JP)

(72) Inventor: Norihito Kuboyama, Hyogo (JP)

(73) Assignee: Risho Kogyo Co., Ltd., Osaka (JP)

(21) Appl. No.: 17/642,656

(22) PCT Filed: Feb. 7, 2022
(86) PCT No.: PCT/JP2022/004646

§ 371 Date: Aug. 10, 2023

(51) Int. Cl. C08L 33/24; C08J 5/24; C08K 3/22; C08K 3/28; C08K 3/38; C09J 7/35; C09J 133/24

(52) U.S. Cl. CPC C08L 33/24; C08J 5/244; C08K 3/22; C08K 3/28; C08K 3/38; C09J 7/35; C09J 133/24; C08K 2003/2227; C08K 2003/282; C08K 2003/385; C08K 5/14; C08L 2205/05; C08L 2312/04

(57) ABSTRACT

Provided is a thermosetting resin composition that can satisfy both low transmission loss and radiation performance even under the same curing conditions as those for conventional substrate materials for high-frequency applications, and also provided are an adhesive sheet, a prepreg, and a laminate.

The thermosetting resin composition comprises a maleimide compound having at least two maleimide groups per molecule, a polyphenylene ether compound having at least two reactive organic groups per molecule, a curing accelerator, and an inorganic filler, wherein the inorganic filler is low-sodium aluminum oxide, and the low-sodium aluminum oxide has an Na⁺ ion content of 10 ppm or less.

### CROSS-REFERENCE TO RELATED APPLICATIONS

The present application is a 371 U.S. National Phase Patent Application based on International Application No. PCT/JP2022/004646, filed Feb. 7, 2022, which claims the benefit of Japanese Patent Application No. 2022-013928, filed Feb. 1, 2022, the entire disclosures of which are hereby expressly incorporated herein by reference.

### BACKGROUND/SUMMARY

The present disclosure relates to a resin composition, an adhesive sheet and a prepreg both using the resin composition, and a laminate using the adhesive sheet or the prepreg.

In next-generation communication systems, it is expected that even larger capacity and higher speed transmission will be promoted in data communications. In the fifth generation mobile communication system (5G), demand for small base stations has increased significantly. In addition to downsizing and space-saving boards used in base stations, there is an increasing demand for high-multilayer boards from both surfaces. Materials with excellent low transmission loss and heat dissipation that enable high-speed communication in the high-frequency region are required.

As conventional substrate materials for high-frequency applications, composite materials obtained by adding spherical silica or hollow silica as an inorganic filler to a main agent, such as a fluororesin, a polyphenylene ether resin, a liquid crystal polymer, or a benzoxazine resin, are generally used (Patent Documents 1 to 3). However, spherical silica and hollow silica as inorganic fillers have low thermal conductivity, and it is difficult to improve heat dissipation.

Accordingly, in order to impart radiation performance, liquid crystal polymers are used as resins, and aluminum oxide, boron nitride, and aluminum nitride are used as inorganic fillers. However, liquid crystal polymers require a very high molding temperature, causing a problem that these are difficult to handle as adhesive sheets or prepregs. In addition, aluminum oxide, boron nitride, and aluminum nitride as inorganic fillers reduce dielectric characteristics; thus, it is difficult for conventional substrate materials for high-frequency applications to satisfy both low transmission loss and heat dissipation.

Accordingly, in view of the conventional problems, an object of the present disclosure is to provide a thermosetting resin composition that can stratify both low transmission loss and radiation performance even under the same curing conditions as those for conventional substrate materials for high-frequency applications, and to also provide an adhesive sheet, a prepreg, and a laminate.

The thermosetting resin composition of the present disclosure comprises a maleimide compound having at least two maleimide groups per molecule, a polyphenylene ether compound having at least two reactive organic groups per molecule, a curing accelerator, and an inorganic filler, wherein the inorganic filler is low-sodium aluminum oxide, and the low-sodium aluminum oxide has an Na+ ion content of 10 ppm or less.

As the inorganic filler, boron nitride or aluminum nitride can be added to the low-sodium aluminum oxide.

The curing accelerator is preferably an organic peroxide having a peroxy group. Further, the organic peroxide having a peroxy group is preferably contained in an amount of 1 to 30 parts by weight based on 100 parts by weight of the maleimide compound.

The polyphenylene ether compound is preferably contained in an amount of 10 to 100 parts by weight, and the aluminum oxide is preferably contained in an amount of 400 to 700 parts by weight, based on 100 parts by weight of the maleimide compound.

The maleimide compound is preferably an aliphatic skeleton maleimide resin, a polyfunctional maleimide resin, or a bisphenol A maleimide resin. Further, the maleimide compound is preferably in a liquid state to which a solvent is added.

The polyphenylene ether compound preferably has a weight average molecular weight Mw of 1000 to 10000.

The adhesive sheet of the present disclosure is an adhesive sheet comprising the thermosetting resin composition and a carrier film, wherein the thermosetting resin composition applied to one surface of the carrier film is in a semi-cured state.

As the carrier film, a copper foil or a PET film can be used.

The prepreg of the present disclosure is a prepreg comprising the thermosetting resin composition and a fiber base material, wherein the thermosetting resin composition impregnated in the fiber base material is in a semi-cured state.

The fiber base material preferably comprises glass fibers, liquid crystal polymer fibers, aramid fibers, carbon fibers, polyester fibers, nylon fibers, acrylic fibers, or vinylon fibers.

The laminate of the present disclosure comprises a single sheet or multiple laminated sheets of the adhesive sheet, from which the carrier film has been removed, followed by heat pressure molding.

The laminate of the present disclosure comprises a single sheet or multiple laminated sheets of the prepreg, which has been subjected to heat pressure molding.

In the laminate, a metal foil is disposed on at least one surface thereof.

In the laminate, a metal foil is disposed on one surface thereof, and a metal plate for heat dissipation is disposed on the other surface.

The thermosetting resin composition of the present disclosure comprises a maleimide compound having at least two maleimide groups per molecule, a polyphenylene ether compound having at least two reactive organic groups per molecule, a curing accelerator, and an inorganic filler, wherein the inorganic filler is low-sodium aluminum oxide, and the low-sodium aluminum oxide has an Na⁺ ion content of 10 ppm or less, whereby a laminate that satisfies both low transmission loss and radiation performance can be formed.

The adhesive sheet of the present disclosure is an adhesive sheet comprising the above thermosetting resin composition and a carrier film, wherein the thermosetting resin composition applied to one surface of the carrier film is in a semi-cured state. A laminate that satisfies both low transmission loss and radiation performance can be realized by using the above adhesive sheet to form the laminate.

The prepreg of the present disclosure is a prepreg comprising the above thermosetting resin composition and a fiber base material, wherein the thermosetting resin composition impregnated in the fiber base material is in a semi-cured state. A laminate that satisfies both low transmission loss and radiation performance can be realized by using the above prepreg to form the laminate.

The laminate of the present disclosure comprises a single sheet or multiple laminated sheets of the above adhesive sheet, from which the carrier film has been removed, followed by heat pressure molding, or a single sheet or multiple laminated sheets of the above prepreg, which has been subjected to heat pressure molding, whereby low transmission loss and radiation performance can be both satisfied.

### BRIEF DESCRIPTION OF THE DRAWINGS

FIG. 1 is a schematic cross-sectional view of the adhesive sheet of the present disclosure.

FIG. 2 is a schematic cross-sectional view of a laminate using an adhesive sheet that is formed as a metal foil-clad laminate.

FIG. 3 is a schematic cross-sectional view of a laminate using a prepreg that is formed as a metal base metal foil-clad laminate.

### DETAILED DESCRIPTION

The thermosetting resin composition, adhesive sheet, prepreg, and laminate of the present disclosure will be described. First, the thermosetting resin composition of the present disclosure will be described.

The thermosetting resin composition of the present disclosure is intended to be used as a substrate material for high-frequency applications, and contains a maleimide compound having at least two maleimide groups per molecule, a polyphenylene ether compound having at least two reactive organic groups per molecule, a curing accelerator, and an inorganic filler.

As the inorganic filler, low-sodium aluminum oxide is used. Low-sodium aluminum oxide is aluminum oxide having an Na⁺ ion content of 10 ppm or less. Further, as the inorganic filler, boron nitride or aluminum nitride can be added to the low-sodium aluminum oxide.

As the curing accelerator, an organic peroxide having a peroxy group is used. If the organic peroxide content is less than 1 part by weight, the reactivity is insufficient. If the organic peroxide content exceeds 30 parts by weight, the characteristics are reduced. Therefore, the organic peroxide is contained in an amount of 1 to 30 parts by weight based on 100 parts by weight of the maleimide compound.

As the maleimide compound, an aliphatic skeleton maleimide resin, a polyfunctional maleimide resin, or a bisphenol A maleimide resin is used. The maleimide resin is used in a liquid state to which a solvent is added, if necessary. Accordingly, the maleimide resin preferably has good solvent solubility.

The polyphenylene ether compound has a weight average molecular weight Mw of 1000 to 10000. If the molecular weight of the polyphenylene ether compound is large, the solvent solubility and reactivity are reduced. Therefore, in consideration of these, it is necessary to use a polyphenylene ether compound with a specific molecular weight.

The thermosetting resin composition contains 10 to 100 parts by weight of the polyphenylene ether compound and 400 to 700 parts by weight of the aluminum oxide based on 100 parts by weight of the maleimide compound, and further contains 1 to 30 parts by weight of the organic peroxide having a peroxy group.

The thermosetting resin composition of the present disclosure is formed by mixing a thermosetting resin comprising a maleimide compound having at least two maleimide groups per molecule, a polyphenylene ether compound having at least two reactive organic groups per molecule, and a curing accelerator with low-sodium aluminum oxide and boron nitride, or low-sodium aluminum oxide and aluminum nitride, as inorganic fillers, and dispersing them by stirring, kneading, or the like. At this time, it is possible to use, if necessary, a surfactant such as a higher fatty acid ester or a copolymer having a functional group, and it is also possible to use a solvent and the like.

The thus-obtained thermosetting resin composition is used to produce the adhesive sheet and prepreg of the present disclosure. Further, the adhesive sheet and the prepreg are used to produce laminates. Next, the adhesive sheet and prepreg of the present disclosure will be described.

The adhesive sheet of the present disclosure comprises the above thermosetting resin composition and a carrier film, and the thermosetting resin composition applied to one surface of the carrier film is in a semi-cured state. The adhesive sheet of the present disclosure is obtained by applying the thermosetting resin composition to one surface of a carrier film, followed by semi-curing by means of heat drying or the like. As the carrier film, a copper foil or a PET film can be used. When the adhesive sheet of the present disclosure is used, the carrier film is removed, resulting in a sheet form of the thermosetting resin composition in a semi-cured state. Therefore, when the thermosetting resin is applied, a release agent can be transferred to the coating surface of the carrier film to thereby make it easy to remove the carrier film.

The prepreg of the present disclosure comprises the above thermosetting resin composition and a fiber base material, and the thermosetting resin composition impregnated in the fiber base material is in a semi-cured state. The prepreg is obtained by impregnating a fiber base material, such as a woven fabric or a non-woven fabric, with the thermosetting resin composition, followed by semi-curing by means of heat drying or the like.

Examples of the fiber base material include glass woven fabrics and the like. As the fibers of the fiber base material, glass fibers, liquid crystal polymer fibers, aramid fibers, carbon fibers, polyester fibers, nylon fibers, acrylic fibers, vinylon fibers, or the like are used.

Next, the laminate of the present disclosure will be described. The laminate of the present disclosure is a laminate comprising the adhesive sheet or the prepreg. The laminate of the present disclosure comprising the adhesive sheet is obtained by removing the carrier film from the adhesive sheet, and sandwiching a single sheet or multiple laminated sheets of the thermosetting resin composition in a semi-cured state by a heating and pressure means, followed by heat pressure molding at a predetermined temperature and pressure.

The laminate of the present disclosure comprising the prepreg is obtained by sandwiching a single sheet or multiple laminated sheets of the prepreg by a metal plate, which is a heating and pressure means, followed by heat pressure molding at a predetermined temperature and pressure.

The laminate of the present disclosure can also be formed as a metal foil-clad laminate having a metal foil on at least one surface thereof. The metal foil-clad laminate is obtained by disposing a metal foil on at least one surface of a single sheet or multiple laminated sheets of the adhesive sheet, or on at least one surface of a single sheet or multiple laminated sheets of the prepreg, followed by heat pressure molding. The material of the metal foil may be any material that can be used as an electrical insulation material, and is not particularly limited; however, a copper foil or an aluminum foil is preferably used.

In addition, the laminate of the present disclosure can also be formed as a metal base metal foil-clad laminate having a metal foil on one surface thereof, and a metal plate for heat dissipation on the other surface. The metal base metal foil-clad laminate is obtained by disposing a metal foil on one surface of a single sheet or multiple laminated sheets of the adhesive sheet, or on one surface of a single sheet or multiple laminated sheets of the prepreg, and disposing a metal base plate for heat dissipation on the other surface, followed by heat pressure molding. As the metal plate for heat dissipation, an aluminum plate, a copper plate, or the like can be used.

The laminate of the present disclosure can satisfy both low transmission loss and radiation performance even under the same curing conditions as those for conventional substrate materials for high-frequency applications, and can satisfy the performance required as a substrate material for high-frequency applications.

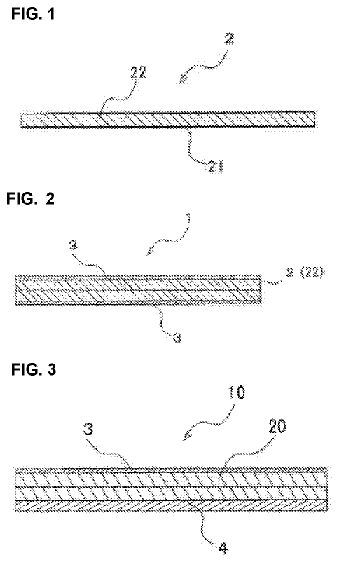

A metal foil-clad laminate 1, which is one configuration of the laminate of the present disclosure, will be described using the drawings. As an example of the metal foil-clad laminate 1, FIG. 2 shows a configuration in which two adhesive sheets 2 are laminated, and a metal foil 3 is disposed on both surfaces thereof. First, the adhesive sheet 2 will be described. A thermosetting resin composition 22 is applied using a bar coater or the like to one surface of a carrier film 21 to a predetermined thickness, and the thermosetting resin composition is heat-dried or the like, thereby obtaining an adhesive sheet 2 in which the thermosetting resin composition 22 is in a semi-cured state, as shown in FIG. 1. At this time, a release agent can be transferred to the coating surface of the carrier film 21 to thereby make it easy to remove the carrier film 21.

Thereafter, the carrier film 21 is removed from the adhesive sheet 2, two sheets of the thermosetting resin composition 22 in a semi-cured state alone are laminated, and two metal foils 3 are separately laid on both surfaces of the two laminated adhesive sheets 2. Then, the resultant is sandwiched by a metal plate, which is a heating and pressure means, followed by heat pressure molding at a predetermined temperature and pressure. As a result, the metal foil-clad laminate 1 having a cross-sectional structure as shown in FIG. 2 is completed.

Further, a metal base metal foil-clad laminate 10, which is another configuration of the laminate of the present disclosure, will be described. As an example of the metal base metal foil-clad laminate 10, FIG. 3 shows a configuration in which two prepregs 20 are laminated, a metal foil 3 is disposed on one surface thereof, and a metal base plate for heat dissipation 4 is disposed on the other surface. For the metal foil-clad laminate 10, a glass woven fabric as a fiber base material is first impregnated with the thermosetting resin composition. Then, the thermosetting resin composition impregnated in the glass woven fabric is heat-dried, thereby obtaining a prepreg 20 in which the thermosetting resin composition in a semi-cured state.

Thereafter, the two prepregs 20 are laminated, a metal foil 3 is disposed on one surface of the two laminated prepregs 20, and a metal base plate for heat dissipation 4 is disposed on the other surface. Then, the resultant is sandwiched by a metal plate, which is a heating and pressure means, followed by heat pressure molding at a predetermined temperature and pressure. As a result, the metal base metal foil-clad laminate 10 having a cross-sectional structure as shown in FIG. 3 is completed.

The laminate of the present disclosure will be described using the Examples. Examples 1 to 3 are laminates using an adhesive sheet, and Example 4 is a laminate using a prepreg. Comparative Examples 1 to 3 are laminates using an adhesive sheet. Examples 1 to 4 and Comparative Examples 1 to 3 will be described in sequence below.

### Example 1

A first resin varnish, which is a thermosetting resin composition, is prepared by uniformly dispersing 600 parts by weight of low-sodium aluminum oxide as an inorganic filler in a thermosetting resin containing 20 parts by weight of a polyphenylene ether resin (weight average molecular weight: 1000 to 10000) and 10 parts by weight of an organic peroxide having a peroxy group as a curing accelerator based on 100 parts by weight of an aliphatic skeleton maleimide resin.

The first resin varnish is applied using a bar coater to one surface of a PET film as a carrier film so that the thickness after molding is 0.1 mm, followed by heat drying, thereby obtaining a first adhesive sheet. A release agent has been transferred to the surface of the carrier film to be coated with the first resin varnish. Then, the carrier film is removed from the first adhesive sheet. A copper foil with a thickness of 0.035 mm is disposed and laminated on both surfaces of the first adhesive sheet from which the carrier film is removed, followed by heat pressure molding at a temperature of 200° C. at a pressure of 2 MPa, thereby obtaining a metal foil-clad laminate with a thickness of 0.1 mm of Example 1.

### Example 2

A second resin varnish, which is a thermosetting resin composition, is prepared by uniformly dispersing 400 parts by weight of low-sodium aluminum oxide and 200 parts by weight of boron nitride as inorganic fillers in a thermosetting resin containing 20 parts by weight of a polyphenylene ether resin (weight average molecular weight: 1000 to 10000) and 10 parts by weight of an organic peroxide having a peroxy group as a curing accelerator based on 100 parts by weight of an aliphatic skeleton maleimide resin.

In the same manner as in Example 1, the second resin varnish is applied using a bar coater to one surface of a PET film as a carrier film so that the thickness after molding is 0.1 mm, followed by heat drying, thereby obtaining a second adhesive sheet. A release agent has been transferred to the surface of the carrier film to be coated with the second resin varnish. Then, the carrier film is removed from the second adhesive sheet. A copper foil with a thickness of 0.035 mm is disposed and laminated on both surfaces of the second adhesive sheet from which the carrier film is removed, followed by heat pressure molding at a temperature of 200° C. at a pressure of 2 MPa, thereby obtaining a metal foil-clad laminate with a thickness of 0.1 mm of Example 2.

### Example 3

A third resin varnish, which is a thermosetting resin composition, is prepared by uniformly dispersing 300 parts by weight of low-sodium aluminum oxide and 300 parts by weight of aluminum nitride as inorganic fillers in a thermosetting resin containing 20 parts by weight of a polyphenylene ether resin (weight average molecular weight: 1000 to 10000) and 10 parts by weight of an organic peroxide having a peroxy group as a curing accelerator based on 100 parts by weight of an aliphatic skeleton maleimide resin.

In the same manner as in Example 1, the third resin varnish is applied using a bar coater to one surface of a PET film as a carrier film so that the thickness after molding is 0.1 mm, followed by heat drying, thereby obtaining a third adhesive sheet. A release agent has been transferred to the surface of the carrier film to be coated with the third resin varnish. Then, the carrier film is removed from the third adhesive sheet. A copper foil with a thickness of 0.035 mm is disposed and laminated on both surfaces of the third adhesive sheet from which the carrier film is removed, followed by heat pressure molding at a temperature of 200° C. at a pressure of 2 MPa, thereby obtaining a metal foil-clad laminate with a thickness of 0.1 mm of Example 3.

### Example 4

The first resin varnish, which is the resin composition of Example 1, is prepared, and glass fibers are prepared as a fiber base material. The glass fibers are impregnated with the first resin varnish so that the thickness after molding is 0.1 mm, followed by heat drying for semi-curing, thereby obtaining a prepreg. Then, a copper foil with a thickness of 0.035 mm is disposed and laminated on both surfaces of the prepreg, followed by heat pressure molding at a temperature of 200° C. at a pressure of 2 MPa, thereby obtaining a metal foil-clad laminate with a thickness 0.1 mm of Example 4.

### Comparative Example 1

A fifth resin varnish is prepared by uniformly dispersing 100 parts by weight of spherical silica as an inorganic filler in a thermosetting resin containing 100 parts by weight of a polyphenylene ether resin (weight average molecular weight: 1000 to 10000) and 10 parts by weight of an organic peroxide as a curing accelerator.

In the same manner as in Example 1, the fifth resin varnish is applied using a bar coater to a PET film as a carrier film so that the thickness after molding is 0.1 mm, followed by heat drying, thereby obtaining a fifth adhesive sheet. A release agent has been transferred to one surface of the carrier film. Then, the carrier film is removed from the fifth adhesive sheet. A copper foil with a thickness of 0.035 mm is disposed and laminated on both surfaces of the fifth adhesive sheet from which the carrier film is removed, followed by heat pressure molding at a temperature of 200° C. at a pressure of 2 MPa, thereby obtaining a metal foil-clad laminate with a thickness of 0.1 mm of Comparative Example 1.

### Comparative Example 2

A sixth resin varnish is prepared by uniformly dispersing 600 parts by weight of aluminum oxide as an inorganic filler in a thermosetting resin containing 0.5 parts by weight of imidazole as a curing accelerator based on 100 parts by weight of an epoxy resin.

In the same manner as in Example 1, the sixth resin varnish is applied using a bar coater to one surface of a PET film as a carrier film so that the thickness after molding is 0.1 mm, followed by heat drying, thereby obtaining a sixth adhesive sheet. A release agent has been transferred to the surface of the carrier film to be coated with the sixth resin varnish. Then, the carrier film is removed from the sixth adhesive sheet. A copper foil with a thickness of 0.035 mm is disposed and laminated on both surfaces of the sixth adhesive sheet from which the carrier film is removed, followed by heat pressure molding at a temperature of 200° C. at a pressure of 2 MPa, thereby obtaining a metal foil-clad laminate with a thickness of 0.1 mm of Comparative Example 2.

### Comparative Example 3

A seventh resin varnish is prepared by uniformly dispersing 600 parts by weight of low-sodium aluminum oxide as an inorganic filler in a thermosetting resin containing 20 parts by weight of a polyphenylene ether resin (weight average molecular weight: 20000 to 50000) and 5 parts by weight of an organic peroxide as a curing accelerator based on 100 parts by weight of a polyfunctional maleimide resin.

In the same manner as in Example 1, the seventh resin varnish is applied using a bar coater to one surface of a PET film as a carrier film so that the thickness after molding is 0.1 mm, followed by heat drying. However, an adhesive sheet could not be obtained.

The metal foil-clad laminates obtained in Examples 1 to 4 and Comparative Examples 1 to 3 were each evaluated in the following manner, and the evaluation results are shown in Table 1.

### Measurement of Relative Permittivity and Dielectric Loss Tangent

A sample of a predetermined size was prepared from the obtained metal foil-clad laminate, and the relative permittivity and dielectric loss tangent were each measured by a cavity resonator (measurement frequency: 10 GHz, according to JIS C2565).

### Measurement of Thermal Conductivity

A sample of a predetermined size was prepared from the obtained metal foil-clad laminate, and the thermal conductivity was measured (according to ASTM D5470) using a steady-state thermal conductivity measurement device.

### Measurement of Storage Elastic Modulus

A sample of a predetermined size was prepared from the obtained metal foil-clad laminate, thermomechanical analysis was carried out using a dynamic viscoelasticity measuring device (DMA), and the storage elastic modulus was measured.

### Copper Foil Peel Strength

By a method according to JIS C6481, a predetermined sample was prepared from the obtained metal foil-clad laminate, the sample was attached to a support fitting after one end of the copper foil was peeled with a suitable length, the end of the peeled copper foil was grasped with a gripping tool, and about 50 mm of the copper foil was continuously peeled off in a direction perpendicular to the copper foil surface at a rate of about 50 mm per minute. The minimum load during this period is taken as the peel strength, which is expressed in kN/m.

TABLE 1

| | | Example | Example | Example | Example | Comparative | Comparative | Comparative |
|---|---|---|---|---|---|---|---|---|
| | | 1 | 2 | 3 | 4 | Example 1 | Example 2 | Example 3 |
| (A) [symbol] resin | [symbol] skeleton | ○ | ○ | ○ | ○ | | | |
| | Polyfunctional | | | | | | | ○ |
| (B) Polyphenylene ether resin | Molecular weight | ○ | ○ | ○ | ○ | ○ | | |
| | (1000-10000) | | | | | | | |
| | Molecular weight | | | | | | | ○ |
| | (20000-50000) | | | | | | | |
| (C) Epoxy resin | | | | | | | ○ | |
| (D) Curing accelerator | Peroxy-based compound | ○ | ○ | ○ | ○ | ○ | | ○ |
| | Imidazole | | | | | | ○ | |
| (E) Inorganic [symbol] | Aluminum oxide | | | | | | ○ | |
| | Aluminum oxide ( [symbol] ) | ○ | ○ | ○ | ○ | | | ○ |
| | Boron nitride | | ○ | | | | | |
| | Aluminum nitride | | | ○ | | | | |
| | Spherical silica | | | | | ○ | | |
| (F) Reinforcing material | Glass fibers | | | ○ | | | | |
| Relative permittivity (10 GHz) | | [symbol] | [symbol] | [symbol] | [symbol] | [symbol] | [symbol] | No sheet |
| Dielectric loss tangent (10 GHz) | | [symbol] | [symbol] | [symbol] | [symbol] | [symbol] | [symbol] | obtained |
| Thermal conductivity | [symbol] | [symbol] | [symbol] | [symbol] | [symbol] | [symbol] | [symbol] | |
| (thickness direction) | | | | | | | | |
| Storage elastic modulus | GPa | [symbol] | [symbol] | [symbol] | [symbol] | [symbol] | [symbol] | |
| Copper foil peel strength | kN/m | [symbol] | [symbol] | [symbol] | [symbol] | [symbol] | [symbol] | |

[symbol]

indicates data missing or illegible when filed

As is clear from Table 1, it is found that Examples 1 to 4 satisfy both excellent dielectric characteristics and high thermal conductivity, and have high copper foil peel strength. Comparative Example 1 has superior dielectric characteristics but has low thermal conductivity, and Comparative Example 2 has high thermal conductivity but has inferior dielectric characteristics. Comparative Example 3 is difficult to handle as an adhesive sheet. Accordingly, it is clearly difficult for Comparative Examples 1 to 3 to satisfy both excellent dielectric characteristics and high thermal conductivity.

In the present disclosure, the combination of an aliphatic maleimide resin and a polyphenylene ether resin as resin components, a peroxy-based compound, and low-sodium aluminum oxide as an inorganic filler makes it possible to realize a laminate that can be used as an insulating substrate material satisfying both low transmission loss and radiation performance, and having high adhesion, and also makes it possible to deal with even larger capacity and higher speed transmission required for next-generation communication systems.

### LIST OF REFERENCE NUMERALS

1. Metal foil-clad laminate
2. Adhesive sheet
20. Prepreg
21. Carrier film
22. Thermosetting resin composition
3. Metal foil
4. Metal plate base
10. Metal base metal foil-clad laminate

1. A thermosetting resin composition comprising a maleimide compound having at least two maleimide groups per molecule, a polyphenylene ether compound having at least two reactive organic groups per molecule, a curing accelerator, and an inorganic filler, wherein:
the inorganic filler is low-sodium aluminum oxide, and
the low-sodium aluminum oxide has an Na⁺ ion content of 10 ppm or less.

2. The thermosetting resin composition according to claim 1, wherein as the inorganic filler, boron nitride or aluminum nitride is added to the low-sodium aluminum oxide.

3. The thermosetting resin composition according to claim 1, wherein the curing accelerator is an organic peroxide having a peroxy group.

4. The thermosetting resin composition according to claim 3, wherein the organic peroxide having a peroxy group is contained in an amount of 1 to 30 parts by weight based on 100 parts by weight of the maleimide compound.

5. The thermosetting resin composition according to claim 1, wherein the polyphenylene ether compound is contained in an amount of 10 to 100 parts by weight, and the aluminum oxide is contained in an amount of 400 to 700 parts by weight, based on 100 parts by weight of the maleimide compound.

6. The thermosetting resin composition according to claim 1, wherein the maleimide compound is an aliphatic skeleton maleimide resin, a polyfunctional maleimide resin, or a bisphenol A maleimide resin.

7. The thermosetting resin composition according to claim 6, wherein the maleimide compound is in a liquid state to which a solvent is added.

8. The thermosetting resin composition according to claim 1, wherein the polyphenylene ether compound has a weight average molecular weight Mw of 1000 to 10000.

9. An adhesive sheet comprising the thermosetting resin composition according to claim 1 and a carrier film,
wherein the thermosetting resin composition applied to one surface of the carrier film is in a semi-cured state.

10. The adhesive sheet according to claim 9, wherein the carrier film is a copper foil or a PET film.

11. A prepreg comprising the thermosetting resin composition according to claim 1 and a fiber base material,
wherein the thermosetting resin composition impregnated in the fiber base material is in a semi-cured state.

12. The prepreg according to claim 11, wherein the fiber base material comprises glass fibers, liquid crystal polymer fibers, aramid fibers, carbon fibers, polyester fibers, nylon fibers, acrylic fibers, or vinylon fibers.

13. A laminate comprising a single sheet or multiple laminated sheets of the adhesive sheet according to claim 9, from which the carrier film has been removed, followed by heat pressure molding.

14. A laminate comprising a single sheet or multiple laminated sheets of the prepreg according to claim 11, which have been subjected to heat pressure molding.

15. The laminate according to claim 13, wherein a metal foil is disposed on at least one surface thereof.

16. The laminate according to claim 13, wherein a metal foil is disposed on one surface thereof, and a metal plate for heat dissipation is disposed on the other surface.
